(19) United States
(12) Patent Application Publication
(10) Pub. No.: US 2019/0088408 A1
(43) Pub. Date: Mar. 21, 2019

(54) WIRING BOARD AND PLANAR TRANSFORMER

(71) Applicant: NGK SPARK PLUG CO., LTD., Nagoya (JP)

(72) Inventors: Masahito MORITA, Yokohama-shi (JP); Kenji SUZUKI, Ichinomiya-shi (JP)

(21) Appl. No.: 16/127,313

(22) Filed: Sep. 11, 2018

(30) Foreign Application Priority Data
Sep. 15, 2017 (JP) 2017-177555

(51) Int. Cl. H01F 27/32; H01F 27/28

(52) U.S. Cl. CPC H01F 27/323; H01F 41/041; H01F 2027/2809; H01F 27/2804

(57) ABSTRACT

Disclosed is a wiring board having: a plurality of insulating layers including a first insulating layer, a second insulating layer opposed to the first insulating layer and at least one intermediate insulating layer located between the first insulating layer and the second insulating layer; at least two wiring layers each located between adjacent two of the insulating layers; and a side surface insulating part covering at least a side surface of the at least one intermediate insulating layer and facing side surfaces of the at least two wiring layers. Each of the first and second insulating layers has an extension portion formed on at least a part of a periphery thereof and extending outwardly of the at least one intermediate insulating layer in a plane direction. The side surface insulating part is arranged between the extension portions of the first and second insulating layers.

### FIELD OF THE INVENTION

The present invention relates to a wiring board and a planar transformer.

### BACKGROUND OF THE INVENTION

There is known a method for manufacturing a multilayer wiring board in which a plurality of insulating layers and a plurality of wiring layers are alternately laminated together, including a process of forming the wiring layers by printing a metal paste on the insulating layers and firing the printed paste. In this method, however, the wiring layers cannot ensure their sufficient thickness so that there would be a limit to the decrease in resistance of the wiring layers.

On the other hand, there is known a process for forming a wiring layer by bonding a metal foil to an insulating layer (see, for example, Japanese Laid-Open Patent Publication No. H11-329842).

### SUMMARY OF THE INVENTION

In the above-mentioned multilayer wiring board, space is created between each adjacent two of the insulating layers when the wiring layers are increased in thickness for decrease in electrical resistance. The presence of such space may lead to the occurrence of surface discharge between the wiring layers, which are isolated by the insulating layer, in the case where the wiring board is placed in e.g. a high-humidity environment. In particular, surface discharge is likely to occur in the case where water drops are adhered to a side surface of the wiring board.

In view of the foregoing, it is an object of the present invention to provide a wiring board capable of suppressing the occurrence of surface discharge between wiring layers even when the wiring layers are increased in thickness. It is also an object of the present invention to provide a planar transformer with such a wiring board.

In accordance with a first aspect of the present invention, there is provided a wiring board, comprising:

a plurality of insulating layers including a first insulating layer, a second insulating layer opposed to the first insulating layer and at least one intermediate insulating layer located between the first insulating layer and the second insulating layer;

at least two wiring layers each located between adjacent two of the plurality of insulating layers; and

a side surface insulating part covering at least a side surface of the at least one intermediate insulating layer and facing side surfaces of the at least two wiring layers,

each of the first and second insulating layers having an extension portion formed on at least a part of a periphery thereof and extending outwardly of the at least one intermediate insulating layer in a plane direction; and

the side surface insulating part being arranged between the extension portion of the first insulating layer and the extension portion of the second insulating layer.

In this configuration, the side surfaces of the intermediate insulating layer and the wiring layers are covered by the side surface insulating part. As the side surface insulating part is arranged between the extension portion of the first insulating layer and the extension portion of the second insulating layer, the side surface insulating part can maintain its adequate width (wall thickness) in the plane direction. It is thus possible to, even when the distance between the insulating layers is increased with increase in the thickness of the wiring layers, reliably suppress the occurrence of surface discharge between the wiring layers by the side surface insulation part. Further, the side surface insulating part is prevented by the extension portions of the first and second insulating layers from projecting outward of the first and second insulating layers in a thickness direction (i.e. from projecting from front and back surfaces of the wiring board). It is thus possible to suppress a deterioration in the flatness of the wiring board.

In accordance with a second aspect of the present invention, there is provided a wiring board as described above, wherein, assuming a minimum distance region as a region in which a distance between the side surfaces of the at least two wiring layers and the side surface of the at least one intermediate insulating layer adjacent thereto in the plane direction is minimum, the side surface insulating part is situated outward of the minimum distance region in the plane direction.

In this configuration, the side surface insulating part is situated outward of the minimum distance region in which surface discharge is likely to occur. It is thus possible to more reliably suppress the occurrence of surface discharge between the wiring layers by the side surface insulating part.

In accordance with a third aspect of the present invention, there is provided a wiring board as described above, wherein each adjacent two of the plurality of insulating layers are apart from each other in the thickness direction; and wherein the wiring board further comprises insulating extension parts each arranged between any adjacent two of the plurality of insulating layers and extending inward from the side surface insulating part in the plane direction.

In this configuration, it is possible to more reliably suppress the occurrence of surface discharge between the wiring layers by the combination of the side surface insulating part and the insulating extension parts.

In accordance with a fourth aspect of the present invention, there is provided a wiring board as described above, wherein the plurality of insulating layers include a plurality of intermediate insulating layers.

The wiring board, when formed with a plurality of intermediate insulating layers, has three or more wiring layers. It is thus possible in this configuration to provide the multilayer wiring board of high quality with three or more wiring layers.

In accordance with a fifth aspect of the present invention, there is provided a wiring board as described above, wherein the side surface insulating part contains an insulating resin material as a main component.

In this configuration, it is possible to relatively easily form the side surface insulating part.

In accordance with a sixth aspect of the present invention, there is provided a wiring board as described above, wherein each of the at least two wiring layers is not fixed to any of the plurality of insulating layers adjacent thereto.

When the wiring layers and the insulating layers expand or contract in accordance with temperature changes, there arises a difference in deformation amount between the wiring layers and the insulating layers due to a difference in thermal expansion coefficient. In this configuration, however, such a deformation amount difference can be absorbed by individual displacements of the wiring layers and the insulating layers. It is thus possible to reduce stress caused between the insulating layers and the wiring layers and suppress the occurrence of a defect such as crack in the insulating layers.

In accordance with a seventh aspect of the present invention, there is provided a wiring board as described above, wherein the plurality of insulating layers contain a ceramic material as a main component.

In this configuration, it is possible to improve the flatness of the insulating layers so that the wiring layers can be arranged at high density over the insulating layers. It is also possible to ensure the high insulation properties of the insulating layers.

In accordance with an eighth aspect of the present invention, there is provided a planer transformer comprising the above-described wiring board.

The other objects and features of the present invention will also become understood from the following description.

### BRIEF DESCRIPTION OF DRAWINGS

FIG. 1 is a schematic cross-sectional view of a wiring board, as taken in parallel to a thickness direction thereof, according to one embodiment of the present invention.

FIG. 2 is a schematic cross-sectional view of the wiring board as taken along line II-II of FIG. 1.

FIG. 3A is a schematic cross-sectional view of a part of the wiring board of FIG. 1 in the vicinity of connection conductors.

FIG. 3B is a schematic cross-sectional view of the wiring board as taken along line IIIB-IIIB of FIG. 3B.

FIG. 4 is a flowchart of a method for manufacturing the wiring board of FIG. 1.

### DESCRIPTION OF EMBODIMENTS

Hereinafter, exemplary embodiments of the present invention will be described below with reference to the drawings.

### 1. Embodiment

[1-1. Structure of Wiring Board]

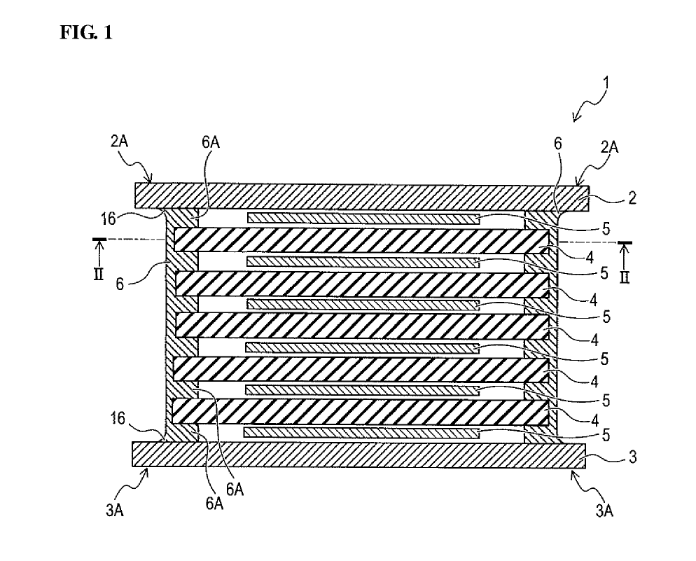

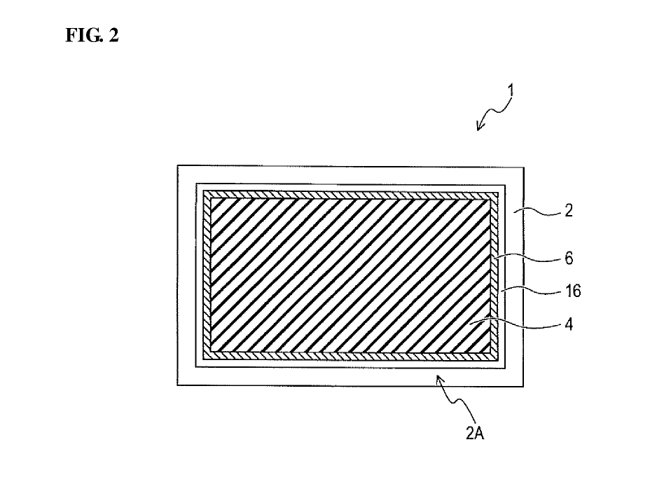

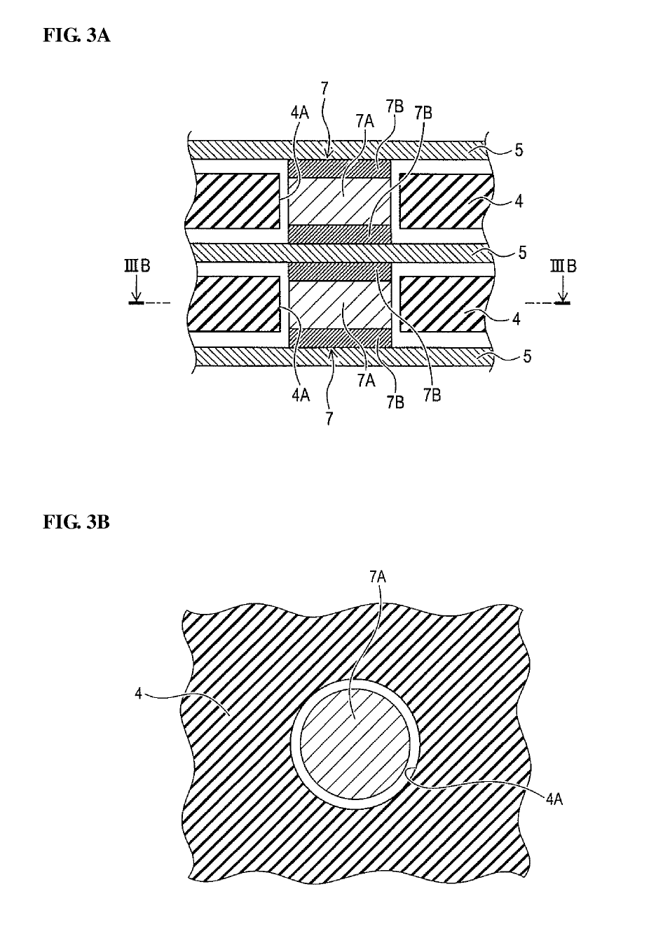

As shown in FIGS. 1 and 2, a wiring board 1 according to one embodiment of the present invention has a plurality of insulating layers (a first insulating layer 2, a second insulating layer 2 and a plurality of intermediate insulating layers 4), a plurality of wiring layers 5, a side surface insulating part 6, a plurality of insulating extension parts 6A and a plurality of connection conductors 7 (see also FIG. 3A) connecting the plurality of wiring layers 5.

Although the wiring board 1 is illustrated as having a multilayer structure with five intermediate insulating layers 4 and six wiring layers 5 in the present embodiment, the number of intermediate insulating layers 4 and the number of wiring layers 5 are not limited to these numbers. The present invention is applicable to the wiring board 1 as long as the wiring board 1 has at least one intermediate insulating layer 4 and at least two wiring layers 5.

Depending on the pattern design of the wiring layers 5, the wiring board 1 can be used for various applications such as a transformer, an insulating gate bipolar transistor (IGBT), a light-emitting diode (LED) illumination device, a power transistor, a motor and the like. The wiring board 1 can particularly suitably be used for high-voltage, high-current applications because of the ease of increasing the thickness of the wiring layers 5.

<Insulating Layers>

Each of the first insulating layer 2, the second insulating layer 3 and the intermediate insulating layers 4 has two opposing front and back surfaces and contains a ceramic material as a main component. Herein, the term “main component” refers to a component contained in an amount of 80 mass % or more. Examples of the ceramic material contained in the insulating layers 2, 3 and 4 are alumina, beryllia, aluminum nitride, boron nitride, silicon nitride, silicon carbide, LTCC (Low Temperature Co-fired Ceramic) and the like. These ceramic materials can be used solely or in combination of two or more thereof.

(First and Second Insulating Layers)

The first insulating layer 2 is provided as one outermost layer of the wiring board 1, whereas the second insulating layer 3 is provided as the other outermost layer of the wiring board 1. As shown in FIG. 1, the plurality of intermediate insulating layers 4 and the plurality of wiring layers 5 are alternately laminated between the first insulating layer 2 and the second insulating layer 3. In other words, the first and second insulating layers 2 and 3 are opposed to and face each other, with the plurality of intermediate insulating layers 4 and the plurality of wiring layers 5 being interposed therebetween.

As shown in FIG. 2, the first insulating layer 2 has an extension portion 2A formed on the entire periphery thereof and extending outward of the plurality of intermediate insulating layers 4 in a plane direction of the first insulating layer 2. Similarly, the second insulating layer 3 has an extension portion 3A formed on the entire periphery thereof and extending outward of the plurality of intermediate insulating layers 4 in a plane direction of the second insulating layer 3. Both of the first and second insulating layers 2 and 3 are hence larger in outer shape than the intermediate insulating layers 4 when viewed in plan.

The extension portions 2A and 3A do not overlap in position with the plurality of intermediate insulating layers 4 when viewed in a thickness direction (i.e. when viewed in plan). The extension portions 2A and 3A are opposed to and face each other in the thickness direction via a space.

Although the first and second insulating layers 2 and 3 have a rectangular planar shape as shown in FIG. 2 in the present embodiment, the planar shape of these insulating layers 2 and 3 may alternatively be any other shape such as polygonal shape other than rectangular, circular shape, oval shape or the like.

(Intermediate Insulating Layers)

The plurality of intermediate insulating layers 4 are located between the first insulating layer 2 and the second insulating layer 3 as mentioned above.

As shown in FIGS. 3A and 3B, at least one through hole 4A is formed through each of the intermediate insulating layers 4 in the thickness direction. This through hole 4A is a via hole in which the connection conductor 7 (as a so-called via conductor) is disposed to establish electrical connection between the wiring layers 5 in the thickness direction. Through holes may also be formed in the first and second insulating layers 2 and 3.

<Wiring Layers>

Each of the wiring layers 5 has two opposing front and back surfaces. The wiring layers 5 shows electrical conductivity and each contains a metal material as a main component. Examples of the metal material contained in the wiring layers 5 are copper, aluminum, silver, gold, platinum, nickel, titanium, chromium, molybdenum, tungsten, alloys thereof and the like. Among others, copper is preferred in terms of cost, electrical conductivity, thermal conductivity and strength. A copper foil or copper plate (sheet) can suitably be used as the wiring layer 5.

As shown in FIG. 1, the plurality of wiring layers 5 are each located between the first insulating layer 2 and one of the intermediate insulating layers 4 adjacent to the first insulating layer 2, between adjacent two of the intermediate insulating layers 4 and between the second insulating layer 3 and another one of the intermediate insulating layers 4 adjacent to the second insulating layer 3. As the wiring layers 5 are relatively large in thickness in the present embodiment, each adjacent two of the insulating layers are apart from each other in the thickness direction. Namely, space is provided between the first insulating layer 2 and the intermediate insulating layer 4 adjacent thereto, between each two adjacent intermediate layers 4 and between the second insulating layer 3 and the intermediate insulating layer 4 adjacent thereto.

Further, each of the wiring layers 5 is apart from and is not fixed to any of the insulating layers 2, 3, 4 adjacent thereto in the present embodiment. In other words, each wiring layer 5 does not have a fixed area and have only a non-fixed area assuming that: the fixed area is an area where the wiring layer 5 is fixed to the insulating layers 2, 3, 4 adjacent thereto; and the non-fixed area is an area where the wiring layer 5 is not fixed to the insulating layers 2, 3, 4 adjacent thereto. It is noted that, since the connection conductor 7 is not joined to the corresponding intermediate insulating layer 4 as will be explained later in the present embodiment, the junction of the wiring layer 5 to the connection conductor 7 is included in the non-fixed area. Thus, the wiring layers 5 are respectively individually displaceable relative to the insulating layers 2, 3, 4 adjacent thereto.

Alternatively, each of the wring layers 5 may be in contact with any of the insulating layers 2, 3, 4 adjacent thereto as long as the wiring layers 5 are respectively individually displaceable relative to the insulating layers 2, 3, 4 adjacent thereto.

<Side Surface Insulating Part>

The side surface insulating part 6 is provided as an insulating member covering side surfaces (i.e. peripheral edge portions) of the intermediate insulating layers 4 and facing side surfaces of the wiring layers 5. The side surface insulating part 6 contains an insulating resin material as a main component. Examples of the insulating resin material contained in the side surface insulating part 6 are epoxy resin, silicone resin, polyurethane resin and the like.

As shown in FIG. 1, the side surface insulating part 6 is arranged between the extension portion 2A of the first insulating layer 2 and the extension portion 3A of the second insulating layer 3. Further, the side surface insulating part 6 is arranged along the entire peripheries of the first and second insulating layers 3 as shown in FIG. 2. More specifically, the side surface insulating part 6 has a tubular shape to connect the opposed inner main surfaces of the first and second insulating layers 2 and 3 (i.e. the back surface of the first insulating layer 2 and the front surface of the second insulating layer 3) in the thickness direction while surrounding the intermediate insulating layers 4 and the wiring layers 5 in the plane direction. In the present embodiment, the side surface insulating part 6 is in contact with the side surfaces of the intermediate insulating layers 4, but is apart from the side surfaces of the wiring layers 5, as shown in FIG. 1.

Herein, assumed is a minimum distance region in which the distance between the side surfaces of the wiring layers 5 and the side surfaces of the intermediate insulating layers 4 adjacent thereto in the plane direction is minimum. In this minimum distance region, surface discharge is likely to occur. As mentioned above, the side surface insulating part 6 is arranged along the entire peripheries of the first and second insulating layers 2 and 3 in the present embodiment. In other words, the side surface insulting part 6 is situated outward of the minimum distance region in the plane direction.

The side surface insulating part 6 has a plurality of hem portions 16 as shown in FIG. 1 in the present embodiment. These hem portions 16 are formed outwardly in the plane direction at joints between the side surface insulating part 6 and the first and second insulating layers 2 and 3.

A width of each of the hem portions 16 in the plane direction (i.e. a surface area of the hem portion 16 in plan view) gradually increases toward the insulating layer 2, 3 in the thickness direction of the wiring board 1 and becomes maximum at the joint between the hem portion 16 and the insulating layer 2, 3. That is, the joints of the side surface insulating part 6 (hem portion 16) to the insulating layers 2 and 3 are larger in width in the plane direction than any other portion of the side surface insulating part 6. The formation of such joints is effective to increase the joint strength between the side surface insulating part 6 and the first and second insulating layers 2 and 3.

<Insulating Extension Parts>

The plurality of insulating extension parts 6A are provided as insulating members extending inward in the plane direction from portions of the side surface insulating part 6 not in contact with the intermediate insulating layers 4. The insulating extension parts 6A can be made of the same material as that of the side surface insulating part 6. In the present embodiment, the insulating extension parts 6A are formed integral with the side surface insulating part 6.

The insulating extension parts 6A are each arranged between adjacent two of the insulating layers 2, 3 and 4 so as to sandwich peripheral edge portions of the intermediate insulating layers 4 between the insulating extension parts 6A in the thickness direction. On the other hand, the insulating extension parts 6A are apart from the wiring layers 5 in the plane direction.

<Connection Conductors>

As shown in FIG. 3A, the plurality of connection conductors 7 are respectively disposed in the through holes 4A of the intermediate insulating layers 4. Each of the connection conductor 7 serves as a so-called via conductor to electrically connect two wiring layers 5 as mentioned above. The connection conductors 7 are each joined to two wiring layers 5 but are not joined to the corresponding intermediate insulating layers 4.

In the present embodiment, each of the connection conductors 7 has a single metal part 7A and junction parts 7B.

The metal part 7A is arranged within the through hole 4A of the intermediate insulating layer 4 so as to electrically connect two wiring layers 5 through the junction parts 7B. There is no particular limitation on the material of the metal part 7A. The metal part 7A can be made of the same metal material as that of the wiring layers 5. It is preferable that the material of the metal part 7A is the same as the main component of the wiring layers 5. The use of such a material is effective to reduce stress caused between the connection conductor 7 and the two wiring layers 5 due to temperature changes.

In the present embodiment, the metal part 7A is in the form of a plate-shaped solid block body that is circular when viewed in plan as shown in FIG. 3B. Herein, the term “block body” refers to a column-like body, a plate-like body, a foil-like body or the like. Assuming that the metal part 7A is projected onto an imaginary plane of the intermediate insulating layer 4 perpendicular to the thickness direction, the projected area of the metal part 7A is smaller than an opening area of the through hole 4A. Namely, a diameter of the metal part 7A in plan view is smaller than a diameter of the through hole 4A. The planar shape of the metal part 7A is not limited to circular and can alternatively be oval, polygonal or the like.

As shown in FIG. 3A, the metal part 7A is apart from and is not fixed to an inner wall of the through hole 4A of the intermediate insulating layer 4 in the present embodiment. Further, a thickness of the metal part 7A is smaller than a depth of the through hole 4A (i.e. a thickness of the intermediate insulating layer 4 in the vicinity of the through hole 4A).

The junction parts 7B show electrical conductivity to electrically connect the metal part 7A to the two wiring layers 5. As the material of the junction parts 7B, there can be used a metal material such as metal brazing material such as silver-copper alloy, solder material such as tin-silver-copper alloy, or the like.

In one connection conductor 7, the junction parts 7B are disposed so as to cover front and back surfaces of the metal part 7A (facing the two wiring layers 5) as shown in FIG. 3A. More specifically, one of the junction parts 7B is joined to the front surface of the metal part 7A and interposed between the front surface of the metal part 7A and the surface of one of the two wiring layers 5; and the other of the junction parts 7B is joined to the back surface of the metal part 7A and interposed between the back surface of the metal part 7A and the surface of the other of the two wiring layers 5. No junction part 713 is provided on a side surface of the metal part 7A facing the inner wall of the through hole 4A of the intermediate insulating layer 4. Furthermore, the junction parts 7B are not joined to the intermediate insulating layer 4. There is space left between the connection conductor 7 and the inner wall of the through hole 4A of the intermediate insulating layer 4.

It is preferable that, in one connector conductor 7, the volume of the metal part 7A is larger than the total volume of the junction parts 7B.

[1-2. Manufacturing Method of Wiring Board]

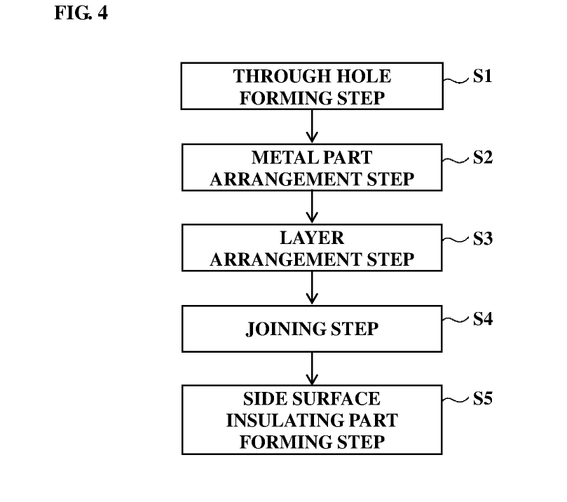

The above-structure wiring board 1 can be manufactured through the following through hole forming step S1, metal part arrangement step S2, layer arrangement step S3, joining step S4 and side surface insulating part forming step S5 as shown in FIG. 4.

<Through Hole Forming Step>

In the through hole forming step S1, the plurality of insulating layers 2, 3 and 4 are provided; and the through holes 4A are formed through the insulating layers 4 in the thickness direction. For example, the through hole forming step S1 can be performed as follows. A slurry is first prepared by mixing a powder of ceramic material with an organic binder, a solvent and an additive such as plasticizer. This slurry is formed into a sheet (substrate) shape by a known technique, thereby yielding a plurality of substrate-shaped green ceramic bodies (called “ceramic green sheets”). The intermediate insulating layers 4 with the through holes 4A are formed by e.g. punching the through holes 4A through portions of the ceramic green sheets and then firing the ceramic green sheets. The first and second insulating layers 2 and 3 are formed by firing the ceramic green sheets without punching.

<Metal Part Arrangement Step>

In the metal part arrangement step S2, the junction parts 7B are laminated on at least parts of the metal parts 7A (more specifically, the front and back surfaces of the metal parts 7A) by the application of metal brazing material or solder material; and then, the metal parts 7A with the junction parts 7B are arranged in the respective through holes 4A of the intermediate insulating layers 4.

<Layer Arrangement Step>

In the layer arrangement step S3, the plurality of insulating layers 2, 3 and 4 (including the intermediate insulating layers 4 in which the metal parts 7A have been arranged along with the junction parts 7B) and the plurality of wiring layers 5 are alternately laminated to one another.

The layer arrangement step S3 may be performed before or in parallel with the metal part arrangement step S2. For example, it is feasible to arrange one wiring layer 5 on the back surface side of one intermediate insulating layer 4, arrange the metal part 7A in the through hole 4A of the one intermediate insulating layer 4, and then, arrange another wiring layer 5 on the front surface side of the one intermediate insulating layer 4.

<Joining Step>

In the joining step S4, each of the metal parts 7A is joined to two of the wiring layers 5 adjacent thereto by heating the laminated layer assembly obtained in the layer arrangement step S3 to thereby melt the junction parts 7B, and then, solidifying the molten material. The connection conductors 7 are formed by this step operation.

<Side Surface Insulating Part Forming Step>

In the side surface insulating part forming step S5, the side surface insulating part 6 is formed between the extension portion 2A of the first insulating layer 2 and the extension portion 3A of the second insulating layer 3. In the present embodiment, the insulating extension parts 6A are formed simultaneously with the side surface insulating part 6. For example, the side surface insulating part forming step S5 can be performed as follows. An insulating resin or a solution (varnish) in which an insulating resin has been dissolved in a solvent is applied to a side surface of the laminated layer assembly obtained in the joining step S4. The applied insulating resin or insulating resin varnish is subjected to heating. When the insulating resin is a photo-curable insulating resin, the applied insulating resin or insulating resin varnish is irradiated with light before the heating. The side surface insulating part 6 and the insulating extension parts 6A are formed by curing of the insulating resin under the heating (or light irradiation and heating).

[1-3. Effects]

In the present embodiment, the following effects are obtained.

(1a) As mentioned above, the side surfaces of the intermediate insulating layers 4 and the wiring layers 5 are covered by the side surface insulating part 6. As the side surface insulating part 6 is arranged between the extension portion 2A of the first insulating layer 2 and the extension portion 3A of the second insulating layer 3, the side surface insulating part 6A can maintain its adequate width (wall thickness) in the plane direction. It is thus possible to, even when the distance between the insulating layers 2, 3, 4 is increased with increase in the thickness of the wiring layers 5, effectively and reliably suppress the occurrence of surface discharge between the wiring layers 5 by the side surface insulating part 6.

(1b) By the extension portions 2A and 3A of the first and second insulating layers 2 and 3, the side surface insulating part 6 is prevented from projecting outward of the first and second insulating layers 2 and 3 in the thickness direction. It is thus possible to suppress a deterioration in the flatness of the wiring board 1.

(1c) In the present embodiment, the side surface insulating part 6 is arranged along the entire periphery of the wiring board 1 and hence is situated outward of the minimum distance region (in which surface discharge is likely to occur) in the plane direction. In this arrangement, it is possible to more reliably suppress the occurrence of surface discharge by the side surface insulating part 6.

(1d) Further, each of the insulating extension parts 6A is arranged between adjacent two of the insulating layers 2, 3, 4. It is thus possible to more reliably suppress the occurrence of surface discharge between the wiring layers 5 by the combination of the side surface insulating part 6 and the insulating extension parts 6A.

(1e) As the insulating resin material is used as the main component of the side surface insulating part 6, it is possible to relatively easily form the side surface insulating part 6.

(1f) Furthermore, each of the wiring layers 5 is not fixed to any of the insulating layers 2, 3, 4 adjacent thereto in the present embodiment. When the wiring layers 5 and the insulating layers 2, 3, 4 expand or contract in accordance with temperature changes, there arises a difference in deformation amount between the wiring layers 5 and the insulating layers 2, 3, 4 due to a difference in thermal expansion coefficient. However, such a deformation amount difference can be absorbed by individual displacements of the wiring layers 5 and the insulating layers 2, 3, 4. It is possible by such displacements to reduce stress caused between the insulating layers 2, 3, 4 and the wiring layers 5 and suppress the occurrence of a defect such as crack in the insulating layers 2, 3, 4.

(1g) As the insulating layers 2, 3, 4 contain a ceramic material as a main component, it is possible to improve the flatness of the insulating layers 2, 3, 4 so that the wiring layers 5 can be arranged at high density over the insulating layers 2, 3, 4. It is also possible by the use of such a ceramic material to ensure the high insulation properties of the insulating layers 2, 3, 4 and thereby enable reliable insulation between the wiring layers 5 even in the case where a relatively large current flows though the wiring layers 5.

### 2. Modification Examples

Although the present invention has been described with reference to the above embodiment, the above embodiment is intended to facilitate understanding of the present invention and is not intended to limit the present invention thereto. Various changes and modifications can be made to the above embodiment without departing from the scope of the present invention.

(2a) In the wiring board 1, the side surface insulating part 6 is not necessarily arranged along the entire periphery of the wiring board 1. That is, the extension portions 2A and 3A are not necessarily formed on the entire peripheries of the first and second insulating layers 2 and 3 and can be formed on at least parts of the peripheries of the first and second insulating layers 2 and 3. It is however preferable that the side surface insulating part 6 is situated at least outward of the minimum distance region in the plane direction as mentioned above.

(2b) The insulating extension parts 6A may be in contact with the side surfaces of the wiring layers 5. The insulating extension parts 6A are not necessarily provided in the wiring board 1, whereby there is no insulating member present between two adjacent insulating layers 2, 3, 4.

The side surface insulating part 6 is not necessary in contact with the side surfaces of all of the intermediate insulating layers 4. The side surface insulating part 6 may be apart from at least parts of the side surfaces of the intermediate insulating layers 4 in the plane direction.

(2c) In the wiring board 1, the plurality of wiring layers 5 may be partially or entirely fixed to the insulating layers 2, 3, 4 adjacent thereto by a metal brazing material or solder material. The connection conductors 7 may be fixed to the insulating layers 4. In other words, each of the wiring layers 5 may have two areas: fixed and non-fixed areas and does not necessarily have a non-fixed area.

(2d) The above-mentioned configuration of the connection conductors 7 in the wiring board 1 is merely one example. For example, the metal parts 7A of the connection conductors 7 may be in spherical form. In place of using the metal parts 7A, it is feasible to respectively arrange metal granular bodies in the through holes 4A and join the metal granular bodies to the wiring layers 5 through joint parts. It is alternatively feasible to arrange a metal rod through the plurality of wiring layers 5 in the thickness direction and join the metal rod to the wiring layers 5 through junction parts.

(2e) The material of the insulating layers 2, 3, 4 is not limited to the ceramic material. The insulating layers 2, 3, 4 may each alternatively contain a resin material, glass material or the like as the main component.

The material of the side surface insulating part 6 is not limited to the resin material. The side surface insulating part 6 may also alternatively contain a ceramic material, glass material or the like as the main component.

(2f) The wiring board 1 is suitably applicable to a planar transformer. In the case of the planar transformer with the wiring board 1, the plurality of wiring layers 5 may respectively have coil wiring patterns at peripheral portions of the adjacent insulating layers 2, 3, 4. In this case, core insertion holes for insertion of a magnetic core (such as ferrite) may be formed in center portions of the insulating layers 2, 3, 4 so as to pass through the coil wiring patterns.

(2g) In the wiring board 1, the plurality of insulating layers 2, 3, 4 are illustrated as having the same thickness; and the plurality of wiring layers 5 are illustrated as having the same thickness. However, the plurality of insulating layers 2, 3, 4 may be of different thicknesses; and the plurality of wiring layers 5 may be of different thicknesses. Further, the plurality of wiring layers 5 may be of different occupation areas.

(2h) It is feasible in the above embodiment to divide the function of one component among a plurality of components or combine the functions of a plurality of components into one. Any of the technical features of the above embodiment may be omitted, replaced or combined as appropriate. All of embodiments and modifications derived from the technical scope of the following claims are included in the present invention.

The entire contents of Japanese Patent Application No. 2017-177555 (filed on Sep. 15, 2017) are herein incorporated by reference.

What is claimed is:

1. A wiring board, comprising:
a plurality of insulating layers including a first insulating layer, a second insulating layer opposed to the first insulating layer and at least one intermediate insulating layer located between the first insulating layer and the second insulating layer;
at least two wiring layers each located between adjacent two of the plurality of insulating layers; and
a side surface insulating part covering at least a side surface of the at least one intermediate insulating layer and facing side surfaces of the at least two wiring layers,
each of the first and second insulating layers having an extension portion formed on at least a part of a periphery thereof and extending outwardly of the at least one intermediate insulating layer in a plane direction; and
the side surface insulating part being arranged between the extension portion of the first insulating layer and the extension portion of the second insulating layer.

2. The wiring board according to claim 1,
wherein, assuming a minimum distance region as a region in which a distance between the side surfaces of the at least two wiring layers and the side surface of the at least one intermediate insulating layer in the plane direction is minimum, the side surface insulating part is situated outward of the minimum distance region in the plane direction.

3. The wiring board according to claim 1, further comprises:
wherein each adjacent two of the plurality of insulating layers are apart from each other in a thickness direction, and
wherein the wiring board further comprises insulating extension parts each arranged between any adjacent two of the plurality of insulating layers and extending inward from the side surface insulating part in the plane direction.

4. The wiring board according to claim 1,
wherein the plurality of insulating layers include a plurality of the intermediate insulating layers.

5. The wiring board according to claim 1,
wherein the side surface insulating part contains an insulating resin material as a main component.

6. The wiring board according to claim 1,
wherein each of the at least two wiring layers is not fixed to any of the plurality of insulating layers adjacent thereto.

7. The wiring board according to claim 1,
wherein the plurality of insulating layers contain a ceramic material as a main component.

8. A planar transformer comprising the wiring board according to claim 1.
